(19) United States
(12) Patent Application Publication
(10) Pub. No.: US 2009/0056801 A1
(43) Pub. Date: Mar. 5, 2009

(54) Thin film solar cell and manufacturing method thereof

(75) Inventors: Lu Chun-Hsiung, Hsinchu City (TW); Bi Chien-Chung, Taichung City (TW)

Correspondence Address: REED SMITH LLP, Suite 1400, 3110 Fairview Park Drive, Falls Church, VA, 22042, US

(73) Assignee: NexPower Technology Corp.

(21) Appl. No.: 12/000,134

(22) Filed: Dec. 10, 2007

(30) Foreign Application Priority Data
Aug. 31, 2007 (CN) 096132385

(51) Int. Cl. H01L 31/0224; H01L 31/18

(52) U.S. Cl. 136/256; 438/98; 257/E31.126

(57) ABSTRACT

The present invention discloses a thin film solar cell and manufacturing method thereof. The thin film solar cell comprises a substrate, a first electrode layer, a photoelectric conversion layer and a second electrode layer. The first electrode layer is formed with a plurality of first grooves so as to divide the first electrode layer into a plurality of unit cells. The photoelectric conversion layer is formed with a plurality of third grooves. A first offset exists between each third groove and each first groove. The second electrode layer is formed with a plurality of second grooves extending downward adequately into the photoelectric conversion layer. A second offset exists between each second groove and each third groove. The thin film solar cell further comprises at least one isolation groove positioned around the second electrode layer; out of projections of the unit cells, and extended downward so as to remove the second electrode layer. The first electrode layer further comprises at least one outer groove that is inside of the isolation groove and is extended downward to the substrate.

### FIELD OF THE INVENTION

The invention relates to a thin film solar cell and manufacturing method thereof that has enhanced effects of isolation.

### DESCRIPTION OF PRIOR ART

Referring to FIGS. 1A to 1C, which shows a conventional thin film solar cell; wherein the thin film solar cell 1 comprises a glass substrate 14, a first electrode layer 11, a semiconductor layer 13, and a second electrode layer 12. In a manufacturing process of the thin film solar cell 1, the first electrode layer 11 is firstly deposited onto the substrate 14, then the first electrode layer 11 is subjected to laser scribing so as to form a plurality of unit cells 112 and first grooves 111; the semiconductor layer 13 is subsequently deposited onto the first electrode layer 11 and then subjected to laser scribing so as to form a plurality of third grooves 131; the third grooves 131 of each semiconductor layer 13 are approximately 100 μm from the first grooves 111 of the first electrode layer 11; the second electrode layer 12 is then deposited onto the semiconductor layer 13, followed by subjecting the second electrode layer 12 and the semiconductor layer 13 to laser scribing, and resulted second grooves 121 are approximately 100 μm from the third grooves 131. By subjecting the aforesaid deposited layers to laser scribing, a thin film solar cell 1 that is comprised of a plurality of unit cells 112 serially connected to each other is resulted.

To prevent problems like short-circuiting and leakage of electrical currents during packaging from occurring, the U.S. Pat. No. 6,300,556 had proposed that an isolation groove 15 be scribed around a solar cell, so as to remove a first electrode layer, a semiconductor layer, and a second electrode layer; in addition, the first electrode layer, the semiconductor layer, and the second electrode layer located at outside of the isolation groove and around the substrate are removed mechanically. Moreover, in the U.S. Pat. No. 6,271,053; after each of the layers have been deposited and divided into a serial-connected solar cell, the second electrode layer and the semiconductor layer around surfaces are removed in order to expose the semiconductor layer, and then the semiconductor layer is allowed to undergo heat treatment so as to oxidize the surface of the semiconductor layer and increase resistance thereof. Furthermore, the U.S. Patent No. 2006/0266409 has proposed to have the second electrode layer and the semiconductor layer cut away by using laser, and then another type of laser is employed to remove the second electrode layer, the semiconductor layer, and the first electrode layer at the original site of laser removal, so as to expose the first electrode layer.

In the aforesaid disclosures, laser of a particular wavelength is used to remove the second electrode layer and the semiconductor layer for forming an isolation groove during the scribing of isolation grooves, and this is because of the difference in characteristics of each of the layers. The same laser is further used to repeatedly scribe the isolation groove for widening the same isolation groove, which helps increase precision for scribing the first electrode layer later. Afterwards, laser of another wavelength is used to scribe the first electrode layer. The fact that the isolation groove needs to be scribed with two different types of laser not only complicates the manufacturing process, but also increases cost of required equipment and manufacturing time. Further, parts of the second electrode layer may elude complete removal after laser scribing due to variations in the distribution of temperature in the laser beam, which will lead to residual amount of the second electrode layer still remain on the first electrode layer, consequently causing short-circuiting of electrical currents. However, if only laser of a single wavelength was used for scribing the three layers, the manufacturing process would be made easier despite that the resulted heat effect would become more severe, and the consequent effect of short-circuiting would be even more obvious. Furthermore, if a step of heat treatment was added at the end of the manufacturing process for oxidizing the semiconductor layer, increasing the resistance, and preventing short-circuiting, the cost of required equipment and the manufacturing time would be raised as well.

### SUMMARY OF THE INVENTION

In light of the aforesaid problems, a thin film solar cell and manufacturing method thereof has been disclosed in the invention. The thin film solar cell at least comprises a substrate, a first electrode layer, a photoelectric conversion layer, and a second electrode layer. The first electrode layer includes a plurality of first grooves for dividing the first electrode layer into a plurality of unit cells. The photoelectric conversion layer is formed with third grooves, and a first offset exists between each third groove and each first groove. The second electrode layer is formed with second grooves; a second offset exists between each second groove and each third groove, and the second grooves extend adequately downward into the photoelectric conversion layer. Said thin film solar cell further comprises at least one isolation groove formed via laser scribing, wet etching, or dry etching, and the isolation groove is positioned around the second electrode layer; out of projections of the unit cells, and extended downward so as to remove the second electrode layer; wherein a width of the isolation groove is increased during a scribing process to enhance isolation thereof. The first electrode layer further comprises at least one outer groove that is extended downward to the substrate and formed inside of the isolation groove, which may cut off pathways of electrical currents and block off flows of electrical currents, thereby preventing short-circuiting from occurring.

Therefore, a primary objective of the invention is to propose a thin film solar cell that has enhanced effects of isolation, thereby preventing the problem of short-circuiting from occurring.

Another objective of the invention is to propose a method for manufacturing the thin film solar cell, which is easy to carry out and may enhance the effects of isolation in the thin film solar cell, thereby preventing the problem of short-circuiting from occurring.

### BRIEF DESCRIPTION OF DRAWINGS

The structure and the technical means adopted by the present invention to achieve the above and other objectives can be best understood by referring to the following detailed description of the preferred embodiments and the accompanying diagrams.

FIGS. 1A, 1B and 1C are schematic views that show a conventional thin film solar cell.

FIGS. 2A, 2B and 2C are schematic views that show a thin film solar cell according to a first preferred embodiment of the invention.

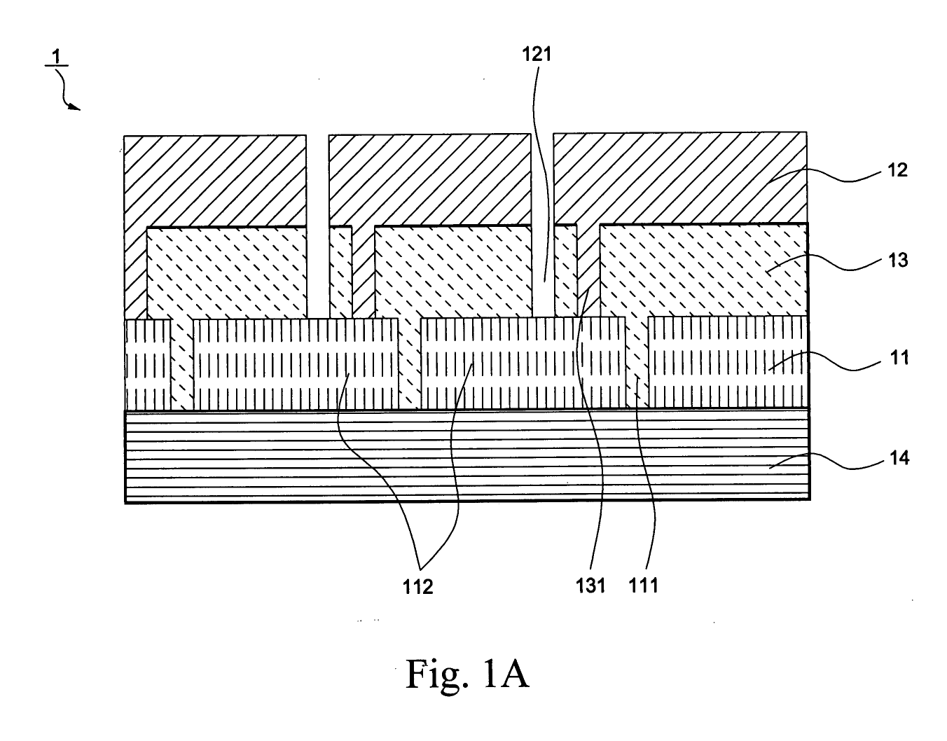

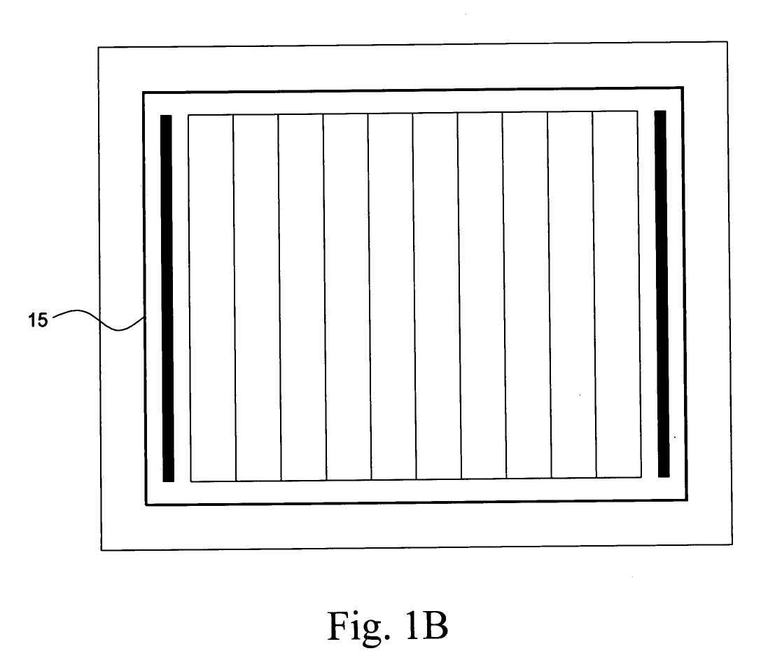

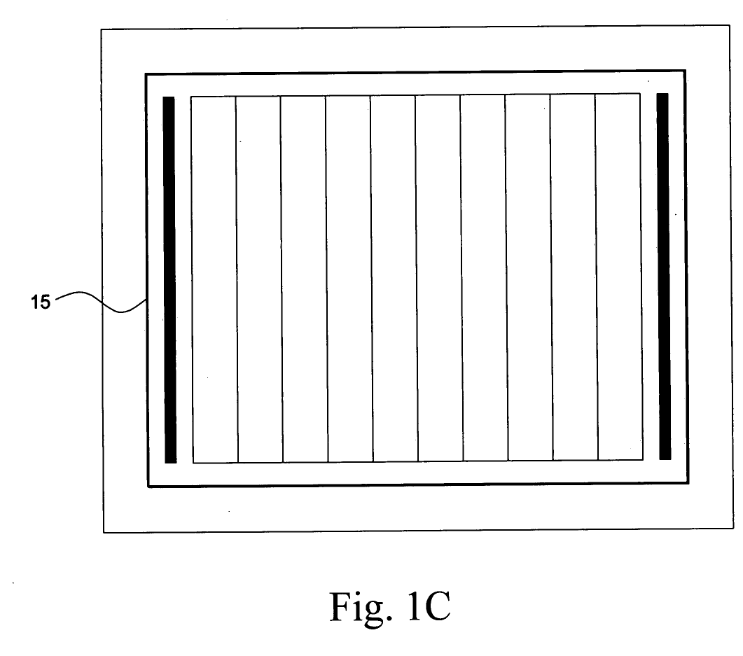

### DETAILED DESCRIPTION OF PREFERRED EMBODIMENTS

A thin film solar cell and manufacturing method thereof has been disclosed in the invention; wherein the principles of photoelectric conversion employed in solar cells may be easily comprehended by those of ordinary skill in relevant technical fields, and thus will not be further described hereafter. Meanwhile, it should be noted that the drawings referred to in the following paragraphs only serve the purpose of illustrating structures related to the characteristics of the disclosure, and are not necessarily drawn according to actual scales and sizes of the disclosed objects.

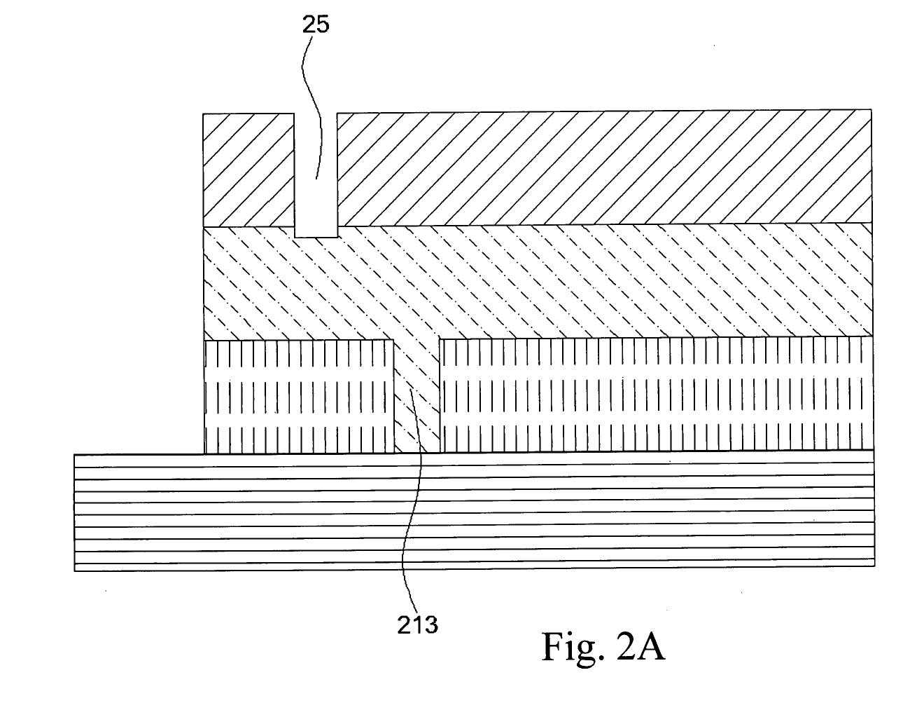

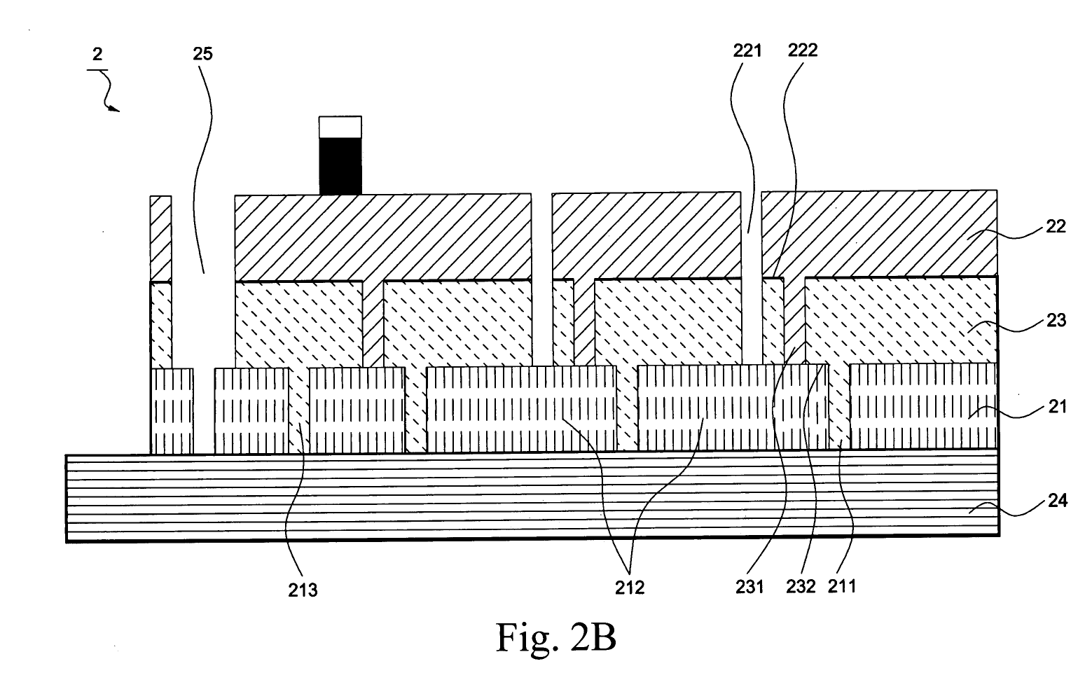

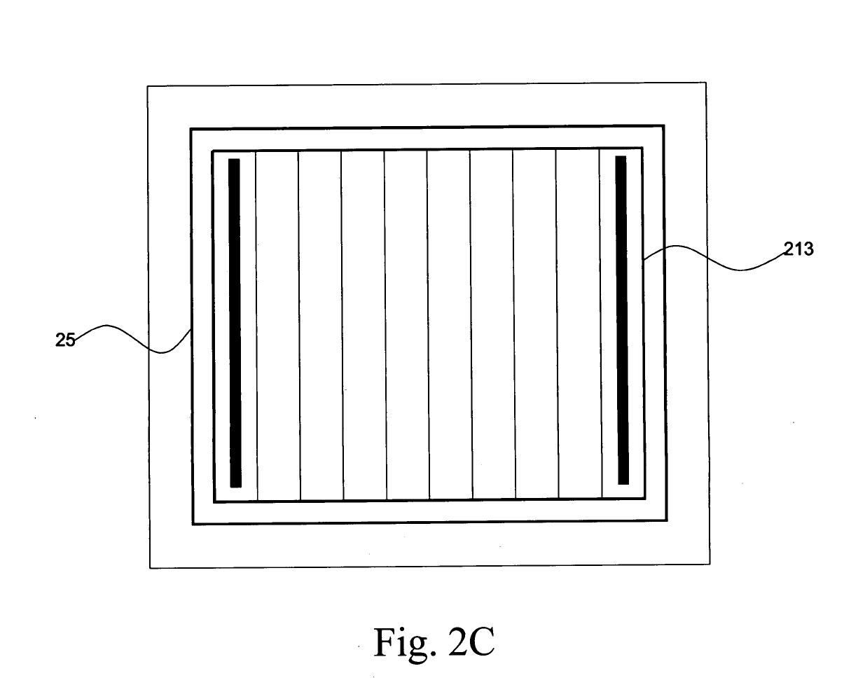

Refer to FIGS. 2A, 2B and 2C, which are schematic views that show a thin film solar cell according to a first preferred embodiment of the invention. Wherein a thin film solar cell 2 at least comprises a substrate 24, a first electrode layer 21, a photoelectric conversion layer 23, and a second electrode layer 22.

The substrate 24 may be made of a material that allows light to pass through, and is preferably a transparent material.

The first electrode layer 21 is formed on top of the substrate 24, and may be formed via methods including sputtering, atmospheric pressure chemical vapor deposition (APCVD), and low pressure chemical vapor deposition (LPCVD). The first electrode layer 21 is preferably made of transparent conductive oxide (TCO), which may include Tin Dioxide (SnO₂), Indium Tin Oxide (ITO), Zinc Oxide (ZnO), Aluminum-doped Zinc Oxide (AZO), Gallium-doped Zinc Oxide (GZO), and Indium Zinc Oxide (IZO). Moreover, the first electrode layer 21 may be a single-layered structure or a multiple-layered structure.

The first electrode layer 21 is formed with a plurality of first grooves 211, so as to divide the first electrode layer 21 into a plurality of unit cells 212, wherein the unit cells 212 are electrically connected to each other via serial connections, parallel connections, or a combination of serial connections and parallel connections.

The photoelectric conversion layer 23 is formed on top of the first electrode layer 21 via deposition mainly, which is made of materials selected from the group consisting of a crystalline silicon semiconductor, an amorphous silicon semiconductor, a compound semiconductor, an organic semiconductor, and a sensitizing dye; the photoelectric conversion layer 23 may be a single-layered structure or a multiple-layered structure.

The photoelectric conversion layer 23 is also formed with third grooves 231, and a first offset 232 exists between each third groove 231 and each first groove 211 of the first electrode layer 21. The first offset 232 ranges from 20 μm to 200 μm, and is preferably between 80 μm to 120 μm.

The second electrode layer 22 is formed on top of the photoelectric conversion layer 23, and may be formed via sputtering or physical vapor deposition (PVD). The second electrode layer 22 may be made of metals, which is selected from the group consisting of silver (Ag), aluminum (Al), chromium (Cr), titanium (Ti), nickel (Ni), gold (Au), and metal alloys thereof. The second electrode layer 22 may further include transparent conductive oxide (TCO), such as Tin Dioxide (SnO₂), Indium Tin Oxide (ITO), Zinc Oxide (ZnO), Aluminum-doped Zinc Oxide (AZO), Gallium-doped Zinc Oxide (GZO), and Indium Zinc Oxide (IZO). Moreover, the second electrode layer 22 may be a single-layered structure or a multiple-layered structure.

Said second electrode layer 22 is formed with second grooves 221 extending downward adequately into the photoelectric conversion layer 23, and a second offset 222 exists between each second groove 221 and each third groove 231 of the photoelectric conversion layer 23. The second offset 222 ranges from 20 μm to 200 μm, and is preferably between 80 μm to 120 μm.

In order to achieve the purpose of isolation, the aforesaid thin film solar cell 2 may further comprise at least one isolation groove 25 that is formed around the second electrode layer 22; out of projections of the unit cells 212, and extended downward so as to remove the second electrode layer 22. To achieve enhanced isolation, the isolation groove 25 may be further extended into a bottom of the photoelectric conversion layer 23, so as to expose the first electrode layer 21.

In order to attain more enhanced isolation than that of the prior arts, at least one outer groove 213 is further included in this invention; the outer groove 213 is formed at the first electrode layer 21 and extended downward to the substrate 24, and may be located inside of the isolation groove 25 so as to block off flows of electrical currents, thereby preventing short-circuiting from occurring.

The first grooves 211, the second grooves 221, the third grooves 231, the isolation groove 25, and the outer groove 213 mentioned above may be formed via methods including laser scribing, wet etching, or dry etching. The first groove 211 is between 20 μm to 150 μm in width, and the width is preferably between 50 μm to 100 μm. The second groove 221 is between 20 μm to 150 μm in width, and the width is preferably between 50 μm to 100 μm. The third groove 231 is between 20 μm to 150 μm in width, and the width is preferably between 50 μm to 100 μm. The isolation groove 25 is between 20 μm to 200 μm in width, and the width is preferably between 50 μm to 150 μm; the width of the isolation groove 25 is no less than widths of any of the first groove 211, the second groove 221, and the third groove 231. The outer groove 213 is between 20 μm to 200 μm in width, and the width is preferably between 50 μm to 150 μm; wherein a distance between the isolation groove 25 and the outer groove 213 is between 20 μm to 150 μm, and the distance is preferably between 50 μm to 100 μm.

A second preferred embodiment is further disclosed in the invention, which is also shown in FIGS. 2A to 2C and illustrates a method for manufacturing the thin film solar cell 2, comprising:

(1) providing a substrate 24;

(2) providing at least a layer of a first electrode layer 21 formed on top of the substrate 24;

(3) scribing the first electrode layer 21 to form a plurality of first grooves 211, so as to divide the first electrode layer 21 into a plurality of unit cells 212;

(4) scribing the first electrode layer 21 to form at least one outer groove 213 that is outside of the unit cells 212 and extended downward into the substrate 24;

(5) providing at least a layer of a photoelectric conversion layer 23 formed on top of the first electrode layer 21;

(6) scribing the photoelectric conversion layer 23 to form a plurality of third grooves 231, and a first offset 232 exists between each of the third grooves 231 and each of the first grooves 211;

(7) providing at least a layer of a second electrode layer 22 formed on top of the photoelectric conversion layer 23;

(8) scribing the second electrode layer 22 to form a plurality of second grooves 221 extending downward adequately into the photoelectric conversion layer 23, and a second offset 222 exists between each of the second grooves 221 and each of the third grooves 231; and

(9) scribing a perimeter of the second electrode layer 22 to form at least one isolation groove 25 out of projections of the outer groove 213, and the isolation groove 25 is extended downward so as to remove the second electrode layer 22.

Characteristics of the substrate 24, the first electrode layer 21, the photoelectric conversion layer 23, the second electrode layer 22, the first grooves 211, the second grooves 221, the third grooves 231, the first offset 232, the second offset 222, the isolation groove 25, and the outer groove 213 mentioned above are as described in the aforesaid first preferred embodiment.

Although a preferred embodiment of the invention has been described for purposes of illustration, it is understood that various changes and modifications to the described embodiment can be carried out without departing from the scope and the spirit of the invention as disclosed in the appended claims.

### BRIEF DESCRIPTION OF NUMBERALS

thin film solar cell 2
first electrode layer 21
first groove 211
unit cell 212
outer groove 213
second electrode layer 22
second groove 221
second offset 222
photoelectric conversion layer 23
third groove 231
first offset 232
substrate 24
isolation groove

What is claimed is:

1. A thin film solar cell, comprising a substrate, a first electrode layer, a photoelectric conversion layer, and a second electrode layer, characterized in that:
the first electrode layer includes a plurality of first grooves so as to divide the first electrode layer into a plurality of unit cells;
the photoelectric conversion layer is formed with a plurality of third grooves;
the second electrode layer is formed with a plurality of second grooves extending downward adequately into the photoelectric conversion layer;
at least one isolation groove is positioned around the second electrode layer; out of projections of the unit cells, and extended downward so as to remove the second electrode layer; and
at least one outer groove is formed at the first electrode layer and extended downward to the substrate, and is located inside of the isolation groove.

2. The thin film solar cell of claim 1, wherein a first offset exists between each of the third grooves and each of the first grooves, a second offset exists between each of the second grooves and each of the third grooves.

3. The thin film solar cell of claim 1, wherein the substrate is made of transparent materials.

4. The thin film solar cell of claim 1, wherein the first electrode layer is made of transparent conductive oxide (TCO), which may be selected from the group consisting of Tin Dioxide (SnO₂), Indium Tin Oxide (ITO), Zinc Oxide (ZnO), Aluminum-doped Zinc Oxide (AZO), Gallium-doped Zinc Oxide (GZO), and Indium Zinc Oxide (IZO); the second electrode layer comprises a metal layer; the metal layer may be selected from the group consisting of silver (Ag), aluminum (Al), chromium (Cr), titanium (Ti), nickel (Ni), and gold (Au).

5. The thin film solar cell of claim 1, wherein the first electrode layer may be a single-layered structure or a multiple-layered structure.

6. The thin film solar cell of claim 1, wherein the photoelectric conversion layer may be a single-layered structure or a multiple-layered structure.

7. The thin film solar cell of claim 1, wherein the photoelectric conversion layer is made of materials selected from the group consisting of a crystalline silicon semiconductor, an amorphous silicon semiconductor, a compound semiconductor, an organic semiconductor, and a sensitizing dye.

8. The thin film solar cell of claim 1, wherein the second electrode layer further comprises transparent conductive oxide (TCO), which may be selected from the group consisting of Tin Dioxide (SnO₂), Indium Tin Oxide (ITO), Zinc Oxide (ZnO), Aluminum-doped Zinc Oxide (AZO), Gallium-doped Zinc Oxide (GZO), and Indium Zinc Oxide (IZO).

9. The thin film solar cell of claim 1, wherein the second electrode layer may be a single-layered structure or a multiple-layered structure.

10. The thin film solar cell of claim 1, wherein the first grooves, the second grooves, the third grooves, the isolation groove, and the outer groove may be formed via laser scribing.

11. The thin film solar cell of claim 1, wherein a width of the isolation groove is not smaller than widths of any of the first grooves, the second grooves, and the third grooves.

12. The thin film solar cell of claim 1, wherein the isolation groove further extends to a bottom of the photoelectric conversion layer, so as to expose the first electrode layer.

13. A method for manufacturing a thin film solar cell, comprising:
providing a substrate;
providing at least a layer of a first electrode layer formed on top of the substrate;
scribing the first electrode layer to form a plurality of first grooves, so as to divide the first electrode layer into a plurality of unit cells;
scribing the first electrode layer to form at least one outer groove that is outside of the unit cells and extended downward into the substrate;
providing at least a layer of a photoelectric conversion layer formed on top of the first electrode layer;
scribing the photoelectric conversion layer to form a plurality of third grooves;
providing at least a layer of a second electrode layer formed on top of the photoelectric conversion layer;
scribing the second electrode layer to form a plurality of second grooves extending downward adequately into the photoelectric conversion layer; and
scribing a perimeter of the second electrode layer to form at least one isolation groove out of projections of the outer groove, and the isolation groove is extended downward so as to remove the second electrode layer.

14. The method for manufacturing a thin film solar cell of claim 18, wherein the substrate is made of transparent materials.

15. The method for manufacturing a thin film solar cell of claim 18, wherein the first electrode layer is made of transparent conductive oxide (TCO), which may be selected from the group consisting of Tin Dioxide (SnO₂), Indium Tin Oxide (ITO), Zinc Oxide (ZnO), Aluminum-doped Zinc Oxide (AZ()), Gallium-doped Zinc Oxide (GZO), and Indium Zinc Oxide (IZO); the second electrode layer comprises, a metal layer; the metal layer may be selected from the group consisting of silver (Ag), aluminum (Al), chromium (Cr), titanium (Ti), nickel (Ni), and gold (Au).

16. The method for manufacturing a thin film solar cell of claim 18, wherein the first electrode layer is deposited onto the substrate via methods selected from the group consisting of sputtering, atmospheric pressure chemical vapor deposition (APCVD), and low pressure chemical vapor deposition (LPCVD).

17. The method for manufacturing a thin film solar cell of claim 18, wherein the first electrode layer may be a single-layered structure or a multiple-layered structure.

18. The method for manufacturing a thin film solar cell of claim 18, wherein the photoelectric conversion layer is formed over the first electrode layer via deposition.

19. The method for manufacturing a thin film solar cell of claim 18, wherein the photoelectric conversion layer may be a single-layered structure or a multiple-layered structure.

20. The method for manufacturing a thin film solar cell of claim 18, wherein the photoelectric conversion layer is made of materials selected from the group consisting of a crystalline silicon semiconductor, an amorphous silicon semiconductor, a compound semiconductor, an organic semiconductor, and a sensitizing dye.

21. The method for manufacturing a thin film solar cell of claim 18, wherein the second electrode layer further comprises transparent conductive oxide (TCO), which may be selected from the group consisting of Tin Dioxide (SnO₂), Indium Tin Oxide (ITO), Zinc Oxide (ZnO), Aluminum-doped Zinc Oxide (AZO), Gallium-doped Zinc Oxide (GZO), and Indium Zinc Oxide (IZO).

22. The method for manufacturing a thin film solar cell of claim 18, wherein the second electrode layer may be a single-layered structure or a multiple-layered structure.

23. The method for manufacturing a thin film solar cell of claim 18, wherein the first grooves, the second grooves, the third grooves, the isolation groove, and the outer groove may be formed via laser scribing.

24. The method for manufacturing a thin film solar cell of claim 18, wherein a width of the isolation groove is not smaller than widths of any of the first grooves, the second grooves, and the third grooves.

25. The method for manufacturing a thin film solar cell of claim 18, wherein the isolation groove further extends to a bottom of the photoelectric conversion layer, so as to expose the first electrode layer.
